(19) United States
(12) Patent Application Publication
(10) Pub. No.: US 2007/0231994 A1
(43) Pub. Date: Oct. 4, 2007

(54) Semiconductor device and fabrication method therefor

(76) Inventors: Toyoji Ito, Toyama (JP); Hiroshi Yoshida, Toyama (JP)

Correspondence Address: MCDERMOTT WILL & EMERY LLP, 600 13TH STREET, NW, WASHINGTON, DC, 20005-3096, US

(21) Appl. No.: 11/706,341

(22) Filed: Feb. 15, 2007

(30) Foreign Application Priority Data
Mar. 29, 2006 (JP) 2006-090119

(51) Int. Cl. H01L 21/8244

(52) U.S. Cl. 438/238

(57) ABSTRACT

A semiconductor device has an interlayer insulating film formed on a substrate and a plurality of capacitors formed in directions of columns on the interlayer insulating film. Each of the capacitors has a lower electrode, a capacitor insulating film, and an upper electrode which are successively stacked in layers in an ascending order. The upper electrodes are formed independently for the individual capacitors formed in the directions of the columns. The capacitor insulating film is formed commonly to each of the capacitors. The side surfaces of each of the upper electrodes and the side surfaces of the capacitor insulating film are formed in continued relation with no stepped portion therebetween.

### CROSS REFERENCE TO RELATED APPLICATIONS

The teachings of Japanese Patent Application JP 2006-90119, filed Mar. 29, 2006, are entirely incorporated herein by reference, inclusive of the claims, specification, and drawings.

### BACKGROUND OF THE INVENTION

The present invention relates to a semiconductor device and a fabrication method therefor and, more particularly, to a semiconductor device having capacitors each using a ferroelectric material or a high dielectric constant material for the capacitor insulating film thereof and a fabrication method therefor.

A ferroelectric material having remanent polarization due to hysteresis characteristics or a high dielectric constant material having a high dielectric constant has been used for the capacitor insulating film of each of capacitors in a semiconductor device such as a nonvolatile memory (FeRAM) or a dynamic random access memory (DRAM).

For example, a ferroelectric memory device comprises capacitors each having an upper electrode, a capacitor insulating film made of a ferroelectric material, and a lower electrode. To implement a high-performance ferroelectric memory device, it is required to form capacitors each having a minimum size and excellent electric characteristics including a reduced amount of leakage current. To satisfy the requirement, various methods for forming capacitors have been proposed.

In terms of miniaturizing capacitors, a method which forms the upper electrode, capacitor insulating film, and lower electrode of each of the capacitors by individually forming an upper-electrode forming film, a capacitor-insulating-film forming film, and a lower-electrode forming film and then simultaneously patterning the three films by using the same mask is most effective (see, e.g., Japanese Laid-Open Patent Publication No. 2001-257320). However, when the upper-electrode forming film, the capacitor-insulating-film forming film, and the lower-electrode forming film have been patterned simultaneously by using the same mask, the side surfaces of the upper electrode, the side surface of the capacitor insulating film, and the side surfaces of the lower electrode are integrally formed with no stepped portion therebetween. As a result, a high voltage is applied to the side end portions of the capacitor insulating film so that a leakage current propagating along the side end portions of the ferroelectric film is more likely to flow between the upper electrode and the lower electrode.

When the ferroelectric film is etched, the highly volatile one of the components of the ferroelectric film is preferentially etched. This leads to the problem that a shift of composition occurs in the side end portions of the ferroelectric film to further increase the amount of leakage current, which causes a degradation of reliability.

To solve the problem, there has been proposed a semiconductor device comprising capacitors in each of which the upper electrode is formed to be larger in planar size than the lower electrode by forming the lower electrode and then performing simultaneous processing of the upper electrode and the ferroelectric film (see, e.g., Japanese Laid-Open Patent Publication No. 2002-198494, p. 35, FIG. 4B, etc.). In accordance with the method, a voltage is scarcely applied to the side end portions of the capacitor insulating film and therefore the amount of leakage current flowing between the upper electrode and the lower electrode can be reduced.

However, the conventional semiconductor device has the problem that the area occupied by the capacitors is increased therein because the planar sizes of the upper electrodes are formed to be larger than those of the lower electrodes.

### SUMMARY OF THE INVENTION

It is therefore an object of the present invention to solve the conventional problem described above and implement a highly reliable semiconductor device by reducing the amount of leakage current propagating along the side end portions of the ferroelectric film of each of capacitors and flowing between the upper and lower electrodes thereof without increasing the area occupied by the capacitors.

To attain the object, the present invention constitutes a semiconductor device such that a capacitor insulating film is integrally formed between capacitors.

Specifically, a semiconductor device according to the present invention comprises: an interlayer insulating film formed on a substrate; and a plurality of capacitors formed in directions of columns on the interlayer insulating film, wherein each of the capacitors has a lower electrode, a capacitor insulating film, and an upper electrode which are stacked in layers in an ascending order, the upper electrodes are independently formed for the individual capacitors formed in the directions of the columns, the capacitor insulating film is formed continuously over the respective lower electrodes of the capacitors, and side surfaces of each of the upper electrodes and side surfaces of the capacitor insulating film are formed in continued relation with no stepped portion therebetween.

In the semiconductor device according to the present invention, there is no possibility that the side surfaces of the capacitor insulating film are in continued relation to the side surfaces of any of the lower electrodes except for those of the capacitors formed on the both end portions of the columns. This obviates the necessity to provide a sufficient overlap margin by considering mask misalignment or the like in the design of the upper electrodes and thereby allows the planar sizes of the upper electrodes to be substantially equal to those of the lower electrodes. As a result, it is possible to improve the reliability of each of the capacitors without increasing the area occupied by the capacitors. In addition, because the side surfaces of each of the upper electrodes are formed in continued relation to the side surfaces of the capacitor insulating film with no stepped portion therebetween, patterning for forming the upper electrodes and patterning for forming the capacitor insulating film can be performed by using the same mask. This prevents the fabrication process steps from being complicated.

In the semiconductor device according to the present invention, a thickness of a portion of the capacitor insulating film which is formed between the individual capacitors is preferably smaller than a thickness of a portion of the capacitor insulating film which is formed on each of the lower electrodes.

In the semiconductor device according to the present invention, those of the plurality of capacitors formed in the directions of the columns which are formed on end portions of the columns are preferably dummy capacitors each of which does not perform charge accumulation. The arrangement can prevent the degradation of the reliability of the semiconductor device even when the side surfaces of the capacitor insulating film of each of the capacitors formed on the end portions of the columns are formed in continued relation to the side surfaces of the lower electrode or when the side surfaces of the capacitor insulating film are formed inwardly of the side surfaces of the lower electrode, each due to mask misalignment or the like.

In the semiconductor device according to the present invention, those of the plurality of capacitors formed in the directions of the columns which are formed on end portions of the columns preferably have the upper electrodes which are larger in planar size than the upper electrodes of the other capacitors and the side surfaces of the upper electrodes of the capacitors formed on the end portions and the side surfaces of the capacitor insulating film thereof are preferably located outwardly of the side surfaces of the lower electrodes thereof on a side opposite to a side on which the capacitors formed on the end portions are adjacent to the other capacitors. The arrangement can prevent the side surfaces of the capacitor insulating film from being formed inwardly of the side surfaces of each of the lower electrodes and thereby improve the reliability of the semiconductor device.

Preferably, the semiconductor device according to the present invention further comprises: a plurality of transistors each formed on the substrate and having diffusion layers; and a plurality of conductive plugs extending through the interlayer insulating film to electrically connect the individual diffusion layers of the transistors to the corresponding ones of the plurality of capacitors, wherein each of the lower electrodes has a multilayer structure including an oxygen barrier film and an electrode film. The arrangement allows the formation of the capacitors on the individual plugs and thereby allows the miniaturization of memory cells.

Preferably, the semiconductor device according to the present invention further comprises: a plurality of capacitors formed in directions of rows intersecting the directions of the columns, wherein the respective upper electrodes of the plurality of capacitors formed in the directions of the rows are electrically connected to form cell plate lines.

In this case, the capacitor insulating film of each of the plurality of capacitors formed in the directions of the rows is preferably integrally formed even between the capacitors formed in the directions of the rows. The arrangement allows a reduction in the amount of leakage current in each of the capacitors when they are formed in rows and columns in a memory cell region.

A method for fabricating a semiconductor device according to the present invention comprises the steps of: (a) forming a plurality of lower electrodes in mutually spaced apart relation in a memory cell region of a substrate; (b) forming an insulating film for filling portions interposed between the individual lower electrodes; (c) forming a capacitor-insulating-film forming film over the individual lower electrodes and the insulating film; (d) forming an upper-electrode forming film on the capacitor-insulating-film forming film; (e) forming a plurality of upper electrodes by patterning the upper-electrode forming film; and (f) forming a capacitor insulating film by removing the capacitor-insulating-film forming film except for the memory cell region, wherein the step (f) includes leaving the capacitor-insulating-film forming film in portions interposed between the individual upper electrodes and forming side surfaces of the upper electrodes and side surfaces of the capacitor insulating film in continued relation.

In the method for fabricating a semiconductor device according to the present invention, there is substantially no possibility that the side surfaces of any of the lower electrodes are formed in continued relation to the side surfaces of the capacitor insulating film. Accordingly, even when the upper electrodes are formed to have planar sizes which are substantially equal to those of the lower electrodes, there is no leakage current propagating along the side end portions of the capacitor insulating film and flowing between each of the upper electrodes and the corresponding lower electrode. As a result, it is possible to implement a highly reliable semiconductor device without increasing the area occupied by the capacitors. In addition, because the capacitor insulating film is formed by patterning the capacitor-insulating-film forming film and removing the capacitor-insulating-film forming film except for the region thereof corresponding to a memory cell region, the capacitor insulating film can be formed without complicating the process steps.

In the method for fabricating a semiconductor device according to the present invention, dry etching is preferably used to form the upper electrodes in the step (e) and form the capacitor insulating film in the step (f).

In the method for fabricating a semiconductor device according to the present invention, a reactive ion etching apparatus is preferably used to form the upper electrodes in the step (e) and form the capacitor insulating film in the step (f) and, when the capacitor insulating film is formed, an RF output of the reactive ion etching apparatus is preferably set lower than when the upper electrodes are formed. When the capacitor insulating film is formed by using dry etching, a pressure inside an etching chamber may be set appropriately higher than when the upper electrodes are formed. When the capacitor insulating film is formed by using dry etching, a gas containing carbon may be used appropriately as an etching gas. The arrangement reduces the linearity of a plasma and thereby allows the capacitor-insulating-film forming film to be left reliability between the individual upper electrodes.

In the method for fabricating a semiconductor device, the step (f) preferably uses the same mask as used in the step (e). The arrangement allows a highly reliable semiconductor device to be implemented without complicating the fabrication process steps.

### BRIEF DESCRIPTION OF THE DRAWINGS

FIGS. 1A and 1B show a semiconductor device according to an embodiment of the present invention, of which FIG. 1A is a plan view thereof and FIG. 1B is a cross-sectional view taken along the line Ib-Ib of FIG. 1A;

FIGS. 2A and 2B show another example of the semiconductor device according to the embodiment of the present invention, of which FIG. 2A is a plan view thereof and FIG. 2B is a cross-sectional view taken along the line IIb-IIb of FIG. 2A;

FIGS. 3A to 3D are cross-sectional views illustrating a method for fabricating the semiconductor device according to the embodiment of the present invention in the order in which the process steps thereof are performed; and

FIGS. 4A to 4C are cross-sectional views illustrating the fabrication method for the semiconductor device according to the embodiment of the present invention in the order in which the process steps thereof are performed.

### DETAILED DESCRIPTION OF THE INVENTION

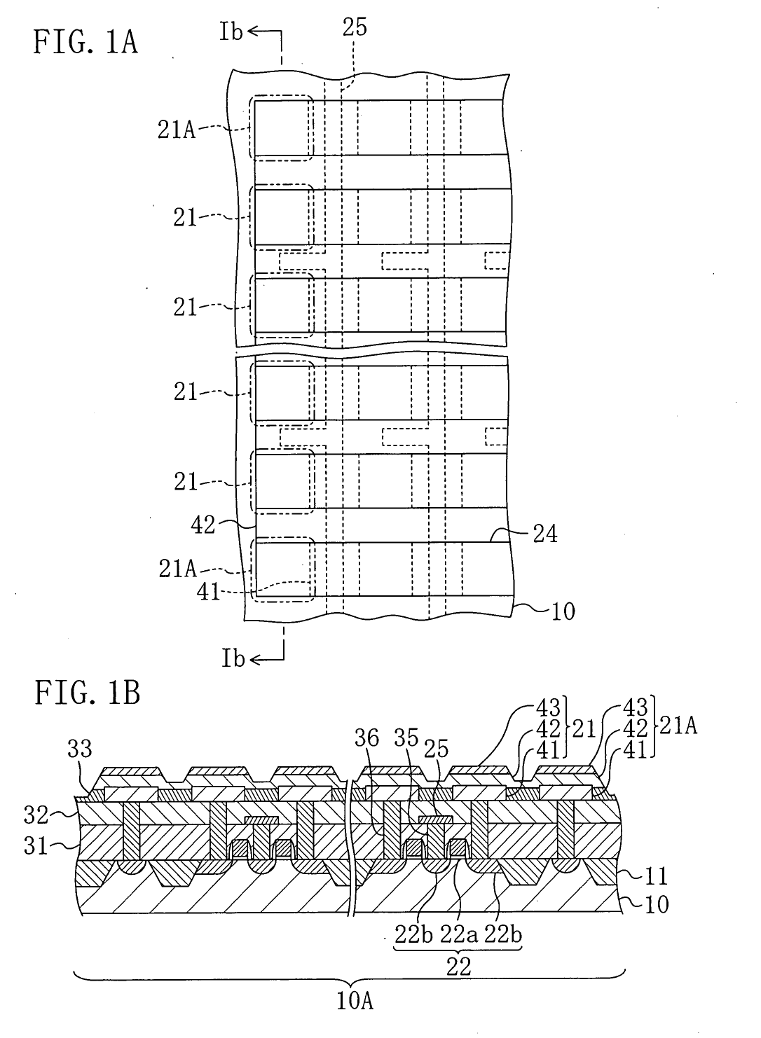

An embodiment of the present invention will be described with reference to the drawings. FIGS. 1A and 1B show a semiconductor device according to the embodiment of the present invention, of which FIG. 1A shows a planar structure thereof and FIG. 1B shows a cross-sectional structure along the line Ib-Ib of FIG. 1A. As shown in FIGS. 1A and 1B, a plurality of memory cells having capacitors 21 and metal oxide film semiconductor (MOS) transistors 22 are arranged in rows and columns in the memory cell region 10A of a semiconductor substrate 10 made of silicon (Si) or the like. In the semiconductor device according to the present embodiment, cell plate lines 24 extend in the directions of rows and bit lines 25 extend in the directions of columns.

The MOS transistors 22 are formed individually in the element formation regions of the semiconductor substrate 10 each defined by a shallow trench isolation (STI) film 11 and have gate electrodes 22a formed on the semiconductor substrate 10 and diffusion layers 22b formed in the semiconductor substrate 10 to be located on the both sides of the gate electrodes 22a.

A first interlayer insulating film 31 made of silicon dioxide (SiO₂) with a thickness of about 400 nm is formed on the semiconductor substrate 10 to cover each of the MOS transistors 22. A plurality of first conductive plugs 35 extending through the first interlayer insulating film 31 and electrically connected individually to the diffusion layers 22b of the corresponding MOS transistors 22 are formed in the first interlayer insulating film 31. Each of the first conductive plugs 35 is made of tungsten (W) and has a barrier layer (not shown) made of titanium (Ti) with a thickness of about 10 nm and titanium nitride (TiN) with a thickness of about 20 nm, which stacked in layers, on a side surface thereof.

The plurality of bit lines 25 made of tungsten (W) with a film thickness of about 100 nm and extending in the directions of the columns are formed on the first interlayer insulating film 31 to be electrically connected individually to the first conductive plugs 35. A second interlayer insulating film 32 made of SiO₂, covering each of the bit lines 25, and having a thickness of about 200 nm above each of the bit lines 25 is formed on the first interlayer insulating film 31.

A plurality of second conductive plugs 36 extending through the first and second interlayer insulating films 31 and 32 and electrically connected individually to the diffusion layers 22b of the corresponding MOS transistors 22 are formed in the first and second interlayer insulating films 31 and 32. Each of the second conductive plugs 36 is made of tungsten (W) and has a barrier layer (not shown) made of titanium (Ti) with a thickness of about 10 nm and titanium nitride (TiN) with a thickness of about 20 nm, which are stacked in layers, on a side surface thereof.

The capacitors 21 are formed on the second interlayer insulating film in mutually spaced apart relation. Each of the capacitors 21 has a lower electrode 41, a capacitor insulating film 42, and an upper electrode 43 formed in this order.

The lower electrodes 41 are formed on the second interlayer insulating film 32 to individually cover the respective upper surfaces of the second conductive plugs 36 and are electrically connected to the corresponding second conductive plugs 36. Each of the lower electrodes 41 contains titanium aluminum nitride (TiAlN) with a thickness of about 50 nm, iridium (Ir) with a thickness of about 50 mm, iridium dioxide (IrO₂) with a thickness of about 50 nm, and platinum (Pt) with a thickness of about 50 nm which are formed in an ascending order. Among them, TiAlN, Ir, and IrO₂ primarily function as oxygen barriers for preventing the oxidation of the second conductive plugs 36 and Pt primarily functions as the electrodes of the capacitors. A third interlayer insulating film 33 made of SiO₂ with a film thickness of about 180 nm is formed on the second interlayer insulating film 32 to be buried in the gaps between the individual lower electrodes 41 and expose the respective upper surfaces of the lower electrodes.

The capacitor insulating film 42 made of a ferroelectric material such as a bismuth layered perovskite type oxide containing strontium (Sr), bismuth (Bi), tantalum (Ta), and niobium (Nb) is formed on each of the lower electrodes 41. The capacitor insulating film 42 remains also on the portions of the third interlayer insulating film 33 which are interposed between the lower electrodes 41 and formed commonly to at least each of the columns. The thickness of the capacitor insulating film 42 is about 100 nm above each of the lower electrodes 41, while it is about 50 nm above the third interlayer insulating film 33. The thickness of each of the portions of the capacitor insulating film 42 which are formed between the individual lower electrodes 41 is smaller than each of the portions thereof which are formed on the lower electrodes 41.

The upper electrodes 43 made of Pt with a thickness of about 50 nm are formed in mutually spaced apart relation to oppose the individual lower electrodes 41. The side surfaces of each of the upper electrodes 43 and the side surfaces of the capacitor insulating film 42 are formed in continued relation. Accordingly, when the upper electrodes 43 and the capacitor insulating film 42 are formed by patterning, the same mask can be used.

The semiconductor device according to the present embodiment is formed such that the width of each of the upper electrodes 43 substantially coincides with the width of each of the lower electrodes 41 within the range of processing variations. This allows the prevention of an increase in the area occupied by the capacitors 21. When a conventional capacitor is formed to have such a structure, the side surfaces of each of the upper electrodes 43, the side surfaces of the capacitor insulating film 42, and the side surfaces of the corresponding lower electrode 41 are undesirably in continued relation. This disadvantageously increases the amount of leakage current which propagates along the side end portions of the capacitor insulating film 42 where the deterioration of composition or the like is likely to occur and flows between the upper electrode 43 and the lower electrode 41. In the semiconductor device according to the present embodiment, however, the capacitor insulating film 42 is integrally formed between the individual capacitors 21. As a result, it is possible to prevent the leakage current from flowing in each of the capacitors formed in a memory cell region. Consequently, the side surfaces of the capacitor insulating film 42 where the leakage current is like to flow are formed only at two capacitors 21A formed on the both end portions of each of the columns. This allows a significant reduction in the amount of leakage current propagating along the side end portions of the capacitor insulating film 42 and flowing between the upper and lower electrodes 43 and 41.

In the region outside the memory cell region 10A, it is required to remove the capacitor insulating film therefrom for the formation of contacts. Accordingly, in the two capacitors 21A formed on the both end portions of each of the columns, the side surfaces of the capacitor insulating film on the side opposite to those opposing the other capacitors are undesirably formed in continued relation to the respective side surfaces of the upper and lower electrodes unless a sufficient overlap margin is provided for the upper electrodes. In addition, there is a possibility that the side surfaces of the capacitor insulating film 42 are formed inwardly of the surfaces of the lower electrodes 41 due to mask misalignment or variations in processing dimensions and the lower ends of the side surfaces of the capacitor insulating film 42 are undesirably in contact with the upper surfaces of the lower electrodes 41. As a result, in the two capacitors 21A formed on the both end portions of each of the columns, the value of the leakage current may increase to significantly degrade the characteristics of the capacitors. To prevent this, the semiconductor device according to the present embodiment uses dummy elements each of which does not perform charge accumulation as the two capacitors 21A formed on the both end portions of each of the columns. This allows the leakage current occurring as a result of propagating along the side end portions of the capacitor insulating film 42 to be substantially ignored.

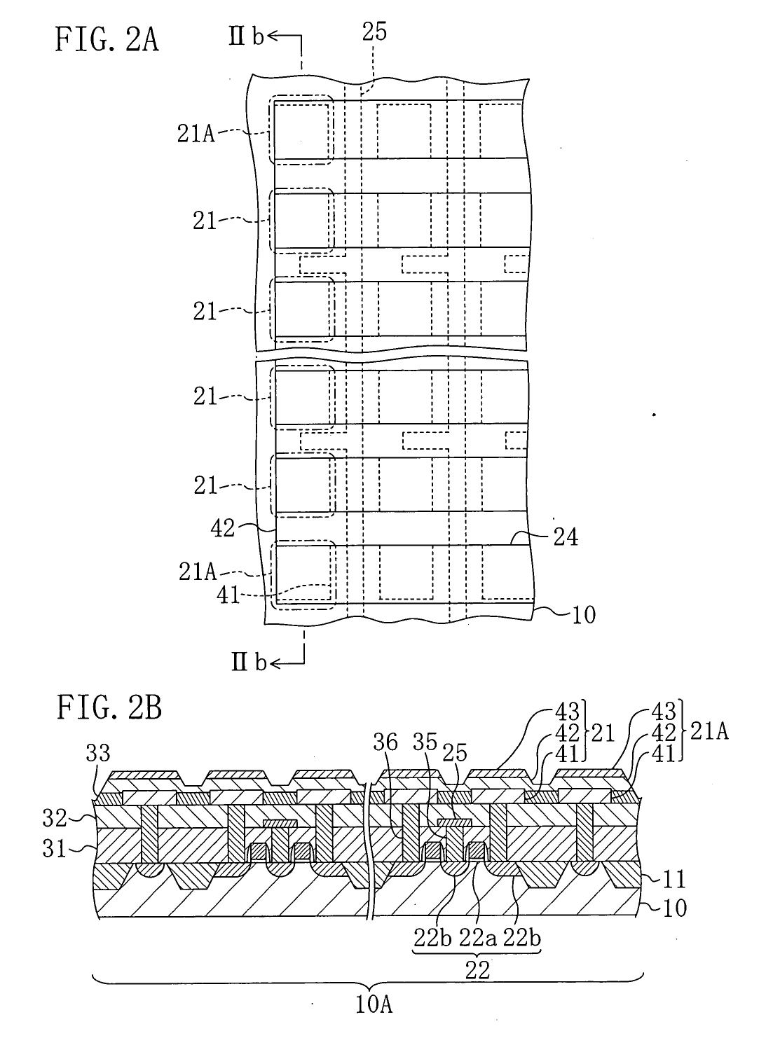

Alternatively, the two capacitors 21A formed on the both end portions of each of the columns may also be designed such that the upper electrodes 43 thereof are larger in planar size than those of the other capacitors 21, as shown in FIG. 2. In the arrangement, even when mask misalignment, variations in processing dimensions, or the like has occurred, the lower ends of the side surfaces formed by the upper electrodes 43 and the capacitor insulating film 42 are kept from contact with the upper surfaces of the lower electrodes 41. This allows the two capacitors 21A formed on the both end portions of each of the columns to be used also as the capacitors of the memory cells.

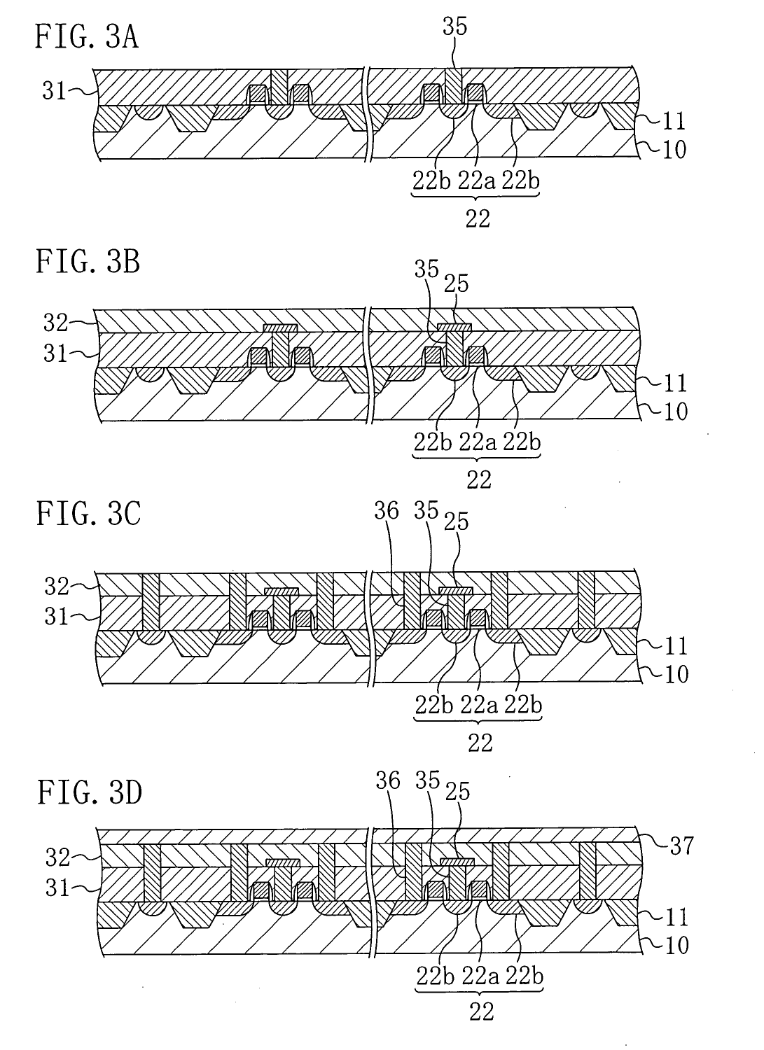

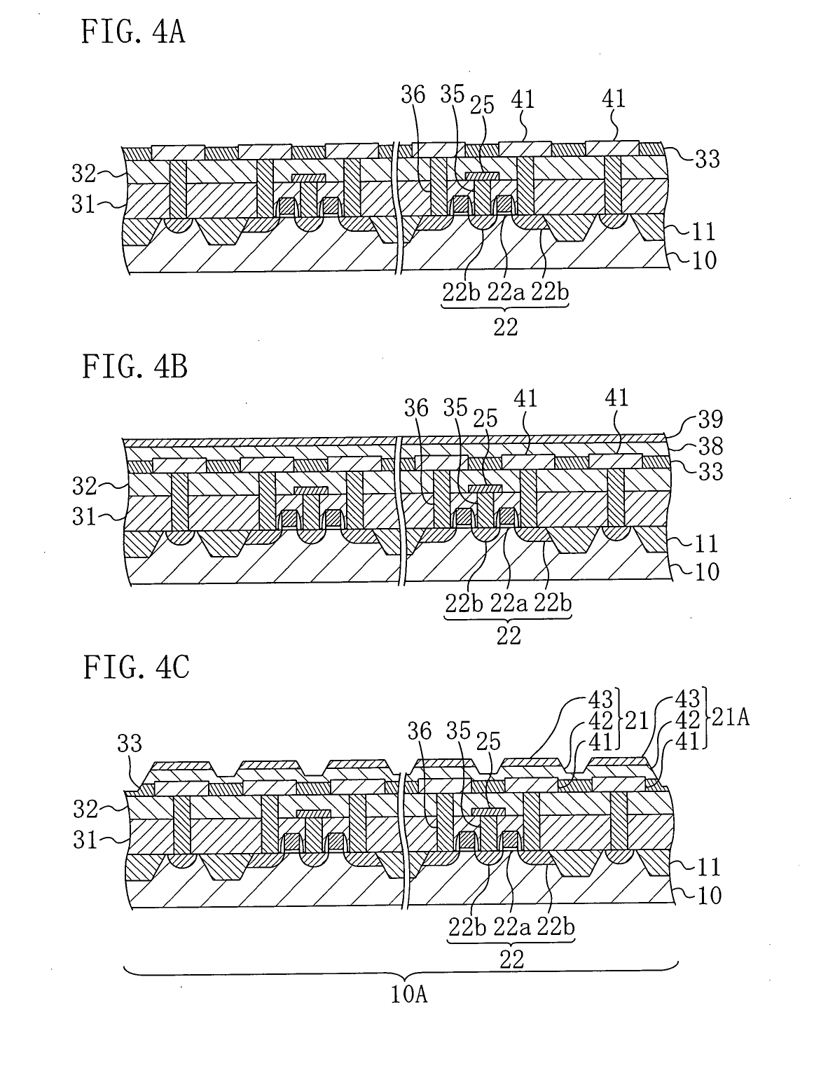

Referring to the drawings, a method for fabricating the semiconductor device according to the present embodiment will be described herein below. FIGS. 3A to 3D and FIGS. 4A to 4C show the cross-sectional structures of the semiconductor device according to the embodiment in the process steps of the fabrication method therefor in the order they are performed.

First, as shown in FIG. 3A, the plurality of STI films 11 are selectively formed in the semiconductor substrate 10 to partition the semiconductor substrate 10 into the plurality of element formation regions. Then, the MOS transistors 22 having the respective gate electrode 22A and the respective diffusion layers 22b are formed individually in the element formation regions by using a normal method. The first interlayer insulating film 31 made of SiO₂ with a thickness of about 800 nm is deposited by chemical vapor deposition (CVD) over the semiconductor substrate 10 to cover the formed MOS transistors 22.

Next, the upper surface of the deposited first interlayer insulating film 31 is planarized by chemical mechanical polishing (CMP) so that the thickness of the first interlayer insulating film 31 is adjusted to be about 400 nm. Then, a plurality of contact holes are formed by lithography and dry etching to extend through the first interlayer insulating film 31 and expose the diffusion layers 22b of the specified MOS transistors 22.

Next, titanium with a thickness of about 10 nm and titanium nitride with a thickness of about 20 nm are deposited by sputtering or CVD over the respective bottom and side surfaces of the contact holes and the first interlayer insulating film 31, thereby forming the barrier layer (not shown). Subsequently, a metal film made of tungsten with a thickness of about 200 nm is deposited by CVD on the barrier layer to fill in the contact holes. Thereafter, the respective portions of the barrier layer and the metal film which are formed on the first interlayer insulating film 31 are removed by CMP so that the plurality of first conductive plugs 35 made of the barrier layer and the metal film and electrically connected to the specified diffusion layers 22b are formed.

Next, as shown in FIG. 3B, a metal film made of tungsten with a thickness of about 100 nm is deposited by sputtering on the first interlayer insulating film 31 to be electrically connected individually to the first conductive plugs 35. Thereafter, the metal film is patterned by lithography and dry etching to form the plurality of bit lines 25 electrically connected individually to the first conductive plugs 35. Subsequently, the second interlayer insulating film 32 made of SiO₂ with a thickness of about 400 nm is deposited by CVD on the first interlayer insulating film 31 to cover each of the bit lines 25. Then, the upper surface of the deposited second interlayer insulating film 32 is planarized by CMP such that the thickness of the second interlayer insulating film 32 above each of the bit lines 25 is adjusted to be about 200 nm.

Next, as shown in FIG. 3C, a plurality of contact holes are formed by lithography and dry etching to extend through the first and second interlayer insulating films 31 and 32 and reach the diffusion layers 22b of the specified MOS transistors 22. Subsequently, titanium with a thickness of about 10 nm and titanium nitride with a thickness of about 20 nm are deposited by sputtering or CVD over the respective bottom and side surfaces of the contact holes and the second interlayer insulating film 32 to form the barrier layer (not shown). Subsequently, a metal film made of tungsten with a thickness of about 200 nm is deposited by CVD on the barrier film to fill in each of the contact holes. Thereafter, the respective portions of the barrier layer and the metal film which are formed on the second interlayer insulating film 32 are removed by CMP so that the plurality of second conductive plugs 36 made of the barrier layer and the metal film and electrically connected individually to the specified diffusion layers 22b are formed.

Next, as shown in FIG. 3D, titanium aluminum nitride with a thickness of about 50 nm, Ir with a thickness of about 50 nm, and IrO2 with a thickness of about 50 nm are deposited by sputtering on the second interlayer insulating film 32 to be electrically connected to each of the second conductive plugs 36, thereby forming a lower-electrode forming film 37.

Next, as shown in FIG. 4A, the lower-electrode forming film 37 is patterned by lithography and dry etching to form the plurality of lower electrodes 41 electrically connected individually to the second conductive plugs 36. Subsequently, the third interlayer insulating film 33 made of SiO₂ with a thickness of about 500 nm is deposited by CVD on the second interlayer insulating film 32 to cover each of the lower electrodes 41.

Thereafter, the upper surface of the third interlayer insulating film 33 is planarized by polishing it by CMP till the upper surface of each of the lower electrodes 41 is exposed. Next, as shown in FIG. 4B, a capacitor-insulating-film forming film 38 made of a ferroelectric material containing Sr, Bi, Ta, and Nb and having a thickness of about 50 nm is deposited by metal organic deposition (MOD) on the third interlayer insulating film 33 to be electrically connected to each of the lower electrodes 41. Subsequently, an upper-electrode forming film 39 made of platinum with a thickness of about 50 nm is deposited by sputtering or CVD on the capacitor-insulating-film forming film 38.

Next, as shown in FIG. 4C, a resist mask (not shown) is formed by lithography. Then, the upper-electrode forming film 39 is patterned by dry etching to form the upper electrodes 43. The etching of the upper-electrode forming film 39 is performed by using an inductively coupled plasma (ICP) dry etching apparatus and using chlorine and argon as etching gases under conditions such that the ICP power is 1000 W, the bias power is 1000 W, and the pressure is 0.5 Pa.

Subsequently, the capacitor-insulating-film forming film 38 is etched by using the resist mask used to form the upper electrodes 43 and the upper electrodes 43 as masks, whereby the portions of the capacitor insulating film 42 which are formed outside the memory cell region 10A and between the individual upper electrodes 43 are etched. The etching of the capacitor-insulating-film forming film 38 is performed by using chlorine and argon as etching gases under conditions such that the ICP power is 1000 W, the bias power is 300 W, and the pressure is 0.5 Pa. By performing etching under such conditions, it is possible to remove the portion of the capacitor-insulating-film forming film 38 which is located outside the memory cell region 10A and leave the portions thereof formed between the individual upper electrodes 43. This is because the bias power is controlled to be lower when the capacitor-insulating-film forming film 38 is etched than when the upper-electrode forming film 39 is etched so that the linearity of a plasma is reduced. Accordingly, an etching rate is lower at the portions of the capacitor-insulating-film forming film 38 which are formed between the individual upper electrodes 43 than at the portion thereof which is formed outside the memory cell region 10A. As a result, it becomes possible to leave the portions of the capacitor-insulating-film forming film 38 which are formed between the individual upper electrodes 43.

Thereafter, specified wires and the like are formed on the semiconductor substrate 10 and a protective insulating film is formed, though they are not depicted. To prevent the degradation of the capacitor insulating film 42 due to hydrogen generated during the formation of the wires and the like, a hydrogen barrier film covering each of the capacitors 21 may also be formed.

Thus, in accordance with the fabrication method for the semiconductor device according to the present embodiment, the etching of the upper-electrode forming film 39 and the etching of the capacitor-insulating-film forming film 38 can be performed by using the single mask pattern. In addition, it is possible in the etching of the capacitor-insulating-film forming film 38 to leave the portions of the capacitor-insulating-film forming film 38 which are located between the capacitors 21 and remove it except for the portion thereof corresponding to the memory cell region 10A. This allows the formation of the capacitors with significantly improved leakage characteristics without increasing the number of process steps.

It is also possible to adjust the pressure inside an etching chamber such that it is higher when the capacitor-insulating-film forming film 38 is etched than when the upper-electrode forming film 39 is etched. For example, the pressure inside the chamber is adjusted to be 0.5 Pa when the upper-electrode forming film 39 is etched and the pressure inside the chamber is adjusted to be 2 Pa when the capacitor-insulating-film forming film 38 is etched. This allows a reduction in the linearity of the plasma and a reduction in etching rate at portions with narrower spacings.

In the etching of the capacitor insulating film 42, it is also possible to add a gas containing carbon such as CHF₃, C₄F₆, C₄F₈, or C₅F₈ to the etching gases. This increases the deposition of an etching product and thereby allows a reduction in etching rate at the portions of the capacitor insulating film 42 which are located between the individual upper electrodes 43.

The bias power, the pressure, and the like during etching may be changed appropriately in accordance with the thickness of the capacitor-insulating-film forming film, the spacings between the upper electrodes, and the like.

Although the present embodiment has described parallel flat plate capacitors, the same effects are also achievable even when the present invention is applied to capacitors having three-dimensional structures such as concave types, columnar types, and cylindrical types.

Although the present embodiment has shown the example in which the memory cells are formed in rows and columns, the same effects can be obtained even when the memory cells are formed in only one row.

Thus, the semiconductor device according to the present invention and the fabrication method therefor can implement a highly reliable semiconductor device by reducing the amount of leakage current propagating along the side end portions of a ferroelectric film and flowing between the upper and lower electrodes of capacitors without increasing the area occupied by the capacitors and are therefore useful as a semiconductor device having capacitors each using a ferroelectric material or a high dielectric constant material for the capacitor insulating film thereof, a fabrication method therefor, and the like.

What is claimed is:

1. A semiconductor device comprising:
an interlayer insulating film formed on a substrate; and
a plurality of capacitors formed in directions of columns on the interlayer insulating film, wherein
each of the capacitors has a lower electrode, a capacitor insulating film, and an upper electrode which are stacked in layers in an ascending order,
the upper electrodes are independently formed for the individual capacitors formed in the directions of the columns,
the capacitor insulating film is formed continuously over the respective lower electrodes of the capacitors, and
side surfaces of each of the upper electrodes and side surfaces of the capacitor insulating film are formed in continued relation with no stepped portion therebetween.

2. The semiconductor device of claim 1, wherein a thickness of a portion of the capacitor insulating film which is formed between the individual capacitors is smaller than a thickness of a portion of the capacitor insulating film which is formed on each of the lower electrodes.

3. The semiconductor device of claim 1, wherein those of the plurality of capacitors formed in the directions of the columns which are formed on end portions of the columns are dummy capacitors each of which does not perform charge accumulation.

4. The semiconductor device of claim 1, wherein those of the plurality of capacitors formed in the directions of the columns which are formed on end portions of the columns have the upper electrodes which are larger in planar size than the upper electrodes of the other capacitors and
the side surfaces of the upper electrodes of the capacitors formed on the end portions and the side surfaces of the capacitor insulating film thereof are located outwardly of the side surfaces of the lower electrodes thereof on a side opposite to a side on which the capacitors formed on the end portions are adjacent to the other capacitors.

5. The semiconductor device of claim 1, further comprising:
a plurality of transistors each formed on the substrate and having diffusion layers; and
a plurality of conductive plugs extending through the interlayer insulating film to electrically connect the individual diffusion layers of the transistors to the corresponding ones of the plurality of capacitors, wherein
each of the lower electrodes has a multilayer structure including an oxygen barrier film and an electrode film.

6. The semiconductor device of claim 1, further comprising:
a plurality of capacitors formed in directions of rows intersecting the directions of the columns, wherein
the respective upper electrodes of the plurality of capacitors formed in the directions of the rows are electrically connected to form cell plate lines.

7. The semiconductor device of claim 6, wherein the capacitor insulating film of each of the plurality of capacitors formed in the directions of the rows is integrally formed even between the capacitors formed in the directions of the rows.

8. A method for fabricating a semiconductor device, the method comprising the steps of:
(a) forming a) plurality of lower electrodes in mutually spaced apart relation in a memory cell region of a substrate;
(b) forming an insulating film for filling portions interposed between the individual lower electrodes;
(c) forming a capacitor-insulating-film forming film over the individual lower electrodes and the insulating film;
(d) forming an upper-electrode forming film on the capacitor-insulating-film forming film;
(e) forming a plurality of upper electrodes by patterning the upper-electrode forming film; and
(f) forming a capacitor insulating film by removing the capacitor-insulating-film forming film except for the memory cell region, wherein
the step (f) includes leaving the capacitor-insulating-film forming film in portions interposed between the individual upper electrodes and forming side surfaces of the upper electrodes and side surfaces of the capacitor insulating film in continued relation.

9. The method of claim 8, wherein dry etching is used to form the upper electrodes in the step (e) and form the capacitor insulating film in the step (f).

10. The method of claim 9, wherein
a reactive ion etching apparatus is used to form the upper electrodes in the step (e) and form the capacitor insulating film in the step (f) and,
when the capacitor insulating film is formed, an RF output of the reactive ion etching apparatus is set lower than when the upper electrodes are formed.

11. The method of claim 9, wherein, when the capacitor insulating film is formed, a pressure inside an etching chamber is set higher than when the upper electrodes are formed.

12. The method of claim 9, wherein, when the capacitor insulating film is formed, a gas containing carbon is used as an etching gas.

13. The method of claim 9, wherein the step (f) uses the same mask as used in the step (e).
